(19) United States
(12) Patent Application Publication
(10) Pub. No.: US 2025/0126705 A1
(43) Pub. Date: Apr. 17, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventor: Eun Su KWON, Suwon-si (KR)

(73) Assignee: SAMSUNG ELECTRO-MECHANICS CO., LTD., Suwon-si (KR)

(21) Appl. No.: 18/678,325

(22) Filed: May 30, 2024

(30) Foreign Application Priority Data
Oct. 17, 2023 (KR) 10-2023-0138204

(51) Int. Cl. H05K 1/02

(52) U.S. Cl. CPC H05K 1/0296; H05K 2201/09036; H05K 2201/09827; H05K 2201/09981

(57) ABSTRACT

The present disclosure relates to a printed circuit board and a manufacturing method of the printed circuit board. The printed circuit board includes: a first insulating layer including a groove portion on an upper side; and a first wiring layer having an embedded portion embedded in the groove portion and a protruding portion protruding onto the first insulating layer. The protruding portion of the first wiring layer has a width of a lower end portion, narrower than a width of an upper end portion.

### CROSS-REFERENCE TO RELATED APPLICATION(S)

This application claims benefit of priority to Korean Patent Application No. 10-2023-0138204 filed on Oct. 17, 2023 in the Korean Intellectual Property Office, the disclosure of which is incorporated herein by reference in its entirety.

### TECHNICAL FIELD

The present disclosure relates to a printed circuit board and a manufacturing method of the printed circuit board.

Multichip packages including memory chips such as High Bandwidth Memories (HBMs), or the like, and processor chips such as Central Processing Units (CPUs), Graphics Processing Units (GPUs), Application Specific Integrated Circuits (ASICs), and Field Programmable Gate Arrays (FPGAs), for data processing that have increased exponentially due to recent developments in artificial intelligence (AI) technology, are being used. In detail, the number of CPU and GPU cores in server products has increased rapidly, and it is necessary to respond to finer chip metal post pitches. Therefore, research is continuing to increase yield along with a structure that can reduce a pitch of circuit patterns of printed circuit boards in response to demand for higher density.

### SUMMARY

An aspect of the present disclosure is to provide a printed circuit board in which a wiring layer having a fine pitch may be implemented, and a manufacturing method of the printed circuit board.

Another aspect of the present disclosure is to provide a printed circuit board in which a wiring layer of which a portion thereof is embedded and another portion thereof protrudes may be implemented, and a manufacturing method of the printed circuit board.

Another aspect of the present disclosure is to provide a printed circuit board having improved reliability, and a manufacturing method of the printed circuit board.

According to an aspect of the present disclosure, provided is a printed circuit board, the printed circuit board including a first insulating layer including a groove portion on an upper side, and a first wiring layer having an embedded portion embedded in the groove portion and a protruding portion protruding onto the first insulating layer. The protruding portion of the first wiring layer has a width of a lower end portion, narrower than a width of an upper end portion.

According to another aspect of the present disclosure, provided is a printed circuit board, the printed circuit board including a first insulating layer including a groove portion on an upper side, a first wiring layer having an embedded portion embedded in the groove portion and a protruding portion protruding onto the first insulating layer, and a second wiring layer embedded below the first insulating layer and spaced apart from the first wiring layer. A wiring density of the first wiring layer is greater than a wiring density of the second wiring layer.

According to another aspect of the present disclosure, provided is a printed circuit board, the printed circuit board including an insulating layer including a groove portion on an upper side; and a wiring layer having an embedded portion embedded in the groove portion and a protruding portion protruding onto the insulating layer. The wiring layer includes a first metal layer disposed on an inner wall of the groove portion, a second metal layer disposed on the first metal layer, and a third layer disposed on the second metal layer. Each of the first, second, and third metal layer includes a portion disposed in the groove portion and a portion protruding onto the insulating layer. The second metal layer includes a different metal than the first metal layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a printed circuit board according to an example;

FIG. 4 is a cross-sectional view schematically illustrating a printed circuit board according to another example;

FIG. 5 is a cross-sectional view schematically illustrating a printed circuit board according to another example;

FIG. 6 is a cross-sectional view schematically illustrating a printed circuit board according to another example;

FIGS. 7 and 8 are cross-sectional views schematically illustrating a manufacturing method of a printed circuit board according to an example;

FIG. 9 is a cross-sectional view schematically illustrating a portion of a manufacturing method of a printed circuit board according to another example; and

FIGS. 10 and 11 are cross-sectional views schematically illustrating a manufacturing method of a printed circuit board according to another example.

### DETAILED DESCRIPTION

Hereinafter, the present disclosure will be described with reference to the accompanying drawings. The shapes and sizes of elements in the drawings may be exaggerated or reduced for clearer descriptions.

### Electronic Device

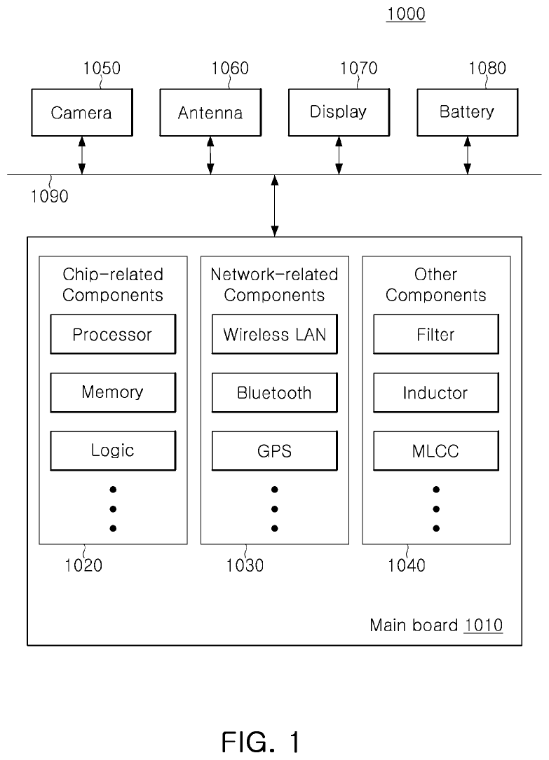

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip related components 1020 may be in the form of a package including the above-described chips or electronic components.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive elements in the form of chip components used for various other purposes, or the like. In addition, other components 1040 may also be combined with each other, with the chip related components 1020 or the network related components 1030 described above.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, or the like. However, these other electronic components are not limited thereto, and may also be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, other electronic components for various uses may also be included, depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device used for processing data.

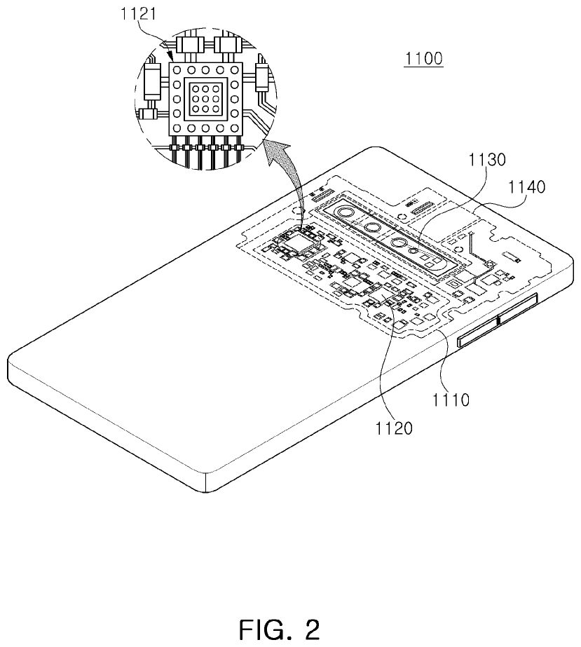

FIG. 2 is a schematic perspective view illustrating an example of an electronic device.

Referring to FIG. 2, the electronic device may be, for example, a smartphone 1100. A motherboard 1110 is accommodated inside the smartphone 1100, and various components 1120 are physically or electrically connected to the motherboard 1110. In addition, other components that may or may not be physically or electrically connected to the motherboard 1110, such as a camera module 1130 and/or a speaker 1140, may be accommodated therein. Some of the electronic components 1120 may be the above-described chip related components, for example, a component package 1121, but are not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and may also be other electronic devices as described above.

### Printed Circuit Board

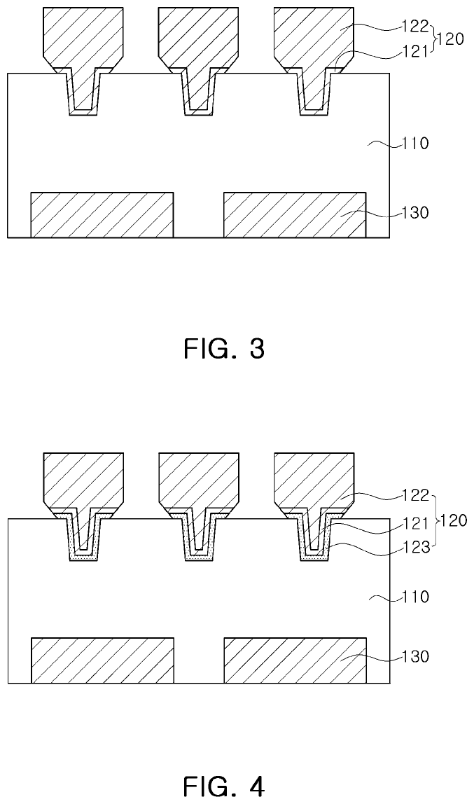

FIG. 3 is a cross-sectional view schematically illustrating a printed circuit board according to an example.

Referring to FIG. 3, the printed circuit board according to an example includes a first insulating layer 110 including a groove portion and a first wiring layer 120 having an embedded portion embedded in the groove portion and a protruding portion protruding onto the first insulating layer 110. The first wiring layer 120 may include a first metal layer 121 disposed on an inner wall of the groove portion and extending along a portion of an upper surface of the first insulating layer 110 and a second metal layer 122 disposed on the first metal layer 121, and the protruding portion of the first wiring layer 120 may have a width of a lower end portion, narrower than a width of an upper end portion.

The first insulating layer 110 may include an insulating material. The insulating material may include thermosetting resins such as epoxy resins, thermoplastic resins such as polyimide, or materials containing these resins along with inorganic fillers, organic fillers, and/or glass fibers (Glass Fiber, Glass Cloth, and/or Glass Fabric). The insulating material may be a photosensitive material and/or a non-photosensitive material. For example, the insulating material of the first insulating layer 110 may be an insulating material of Prepreg (PPG) or Resin Coated Copper (RCC), but is not limited thereto, and may be Ajinomoto Build-up Film (ABF), Photo Imageable Dielectric (PID), FR-4, Bismaleimide Triazine (BT), or the like. However, the present disclosure is not limited thereto, and if necessary, other polymer materials with excellent rigidity may be used.

The first insulating layer 110 may have a groove portion on an upper side. The groove portion is a portion in which at least a portion of the upper side of the first insulating layer 110 is removed, and may penetrate a portion of the first insulating layer 110. The groove portion may only penetrate a portion of the first insulating layer 110 and may not penetrate all of the first insulating layer 110 so that the upper and lower surfaces of the first insulating layer 110 are connected. The groove portion may be formed by etching a portion of the first insulating layer 110 from the upper side of the first insulating layer 110, but the present disclosure is not limited thereto. The groove portion may be formed by using any method in which a portion of the first insulating layer 110 may be removed to form a groove portion penetrating a portion thereof on one side of the first insulating layer 110 without limitation.

The first wiring layer 120 may include a first metal layer 121 and a second metal layer 122 disposed on the first metal layer 121. The first wiring layer 120 may include a metal material. The metal material may be copper (Cu), aluminum (Al), silver (Ag), tin (Sn), gold (Au), lead (Pb), titanium (Ti), or alloys thereof. The first wiring layer 120 may preferably include copper (Cu), but the present disclosure is not limited thereto, and as the first wiring layer 120 may include a first metal layer 121 and a second metal layer 122, each of the metal layers may include different metal materials.

The first wiring layer 120 may perform various functions depending on the design. For example, the first wiring layer 120 may include a signal pattern, a power pattern, a ground pattern, and the like, but the present disclosure is not limited thereto, and may function as a pad on which electronic components and chips may be mounted. Each of these patterns can have various forms such as lines, planes, pads, and the like. A portion of the first wiring layer 120 may be embedded in the first insulating layer 110, and another portion of the first wiring layer 120 may protrude onto the first insulating layer 110. In this case, the embedded portion of the first wiring layer 120 may not completely penetrate the first insulating layer 110, and may be formed to only partially penetrate the first insulating layer 110. Specifically, the first wiring layer 120 may be formed by filling a groove portion penetrating a portion of the first insulating layer 110, but the present disclosure is not limited thereto. Another portion of the first wiring layer 120 may be disposed on the first insulating layer 110 to form a protruding portion protruding beyond the first insulating layer 110. A width of the embedded portion of the first wiring layer 120 may be narrower than a width of the protruding portion of the first wiring layer 120. This may be a result of forming a groove portion having a finer width than a wiring width, in a protruding portion of the first wiring layer 120.

The first metal layer 121 may include one metal material from the group of metal materials of the above-described first wiring layer 120. The first metal layer 121 may preferably include copper (Cu), but the present disclosure is not limited thereto, and the first metal layer 121 may be comprised of a plurality of metal layers in some cases. In this case, when the first metal layer 121 is comprised of a plurality of metal layers, each of the plurality of metal layers may include different metal materials. The first metal layer 121 may function as a seed for forming the second metal layer 122. The first metal layer 121 may include an electroless plating layer (or chemical copper), a sputtering layer, or both thereof, if necessary.

The first metal layer 121 may be disposed on an inner wall of the groove portion and extend to a portion of upper side of the first insulating layer 110. The first metal layer 121 may form an embedded portion of the first wiring layer 120 or a protruding portion of the first wiring layer 120. The first metal layer 121 may be disposed conformally along the groove portion formed in the first insulating layer 110. That is, the first metal layer 121 may be formed along the inner wall of the groove portion formed in the first insulating layer 110, and may be disposed to extend to the upper surface of the first insulating layer 110.

The second metal layer 122 may include one metal material from the group of metal materials of the above-described first wiring layer 120. The second metal layer 122 may include substantially the same metal material as the first metal layer 121. For example, the second metal layer 122 may preferably include copper (Cu), but the present disclosure is not limited thereto. The second metal layer 122 may include an electroplating layer (or electrolytic copper), and, if necessary, may further include other components necessary for electroplating. The second metal layer 122 may be formed by performing electroplating using the first metal layer 121 as a seed, but the present disclosure is not limited thereto.

The second metal layer 122 may be disposed on the first metal layer 121, and the second metal layer 122 may also form an embedded portion of the first wiring layer 120, and may form a protruding portion of the first wiring layer 120. That is, a portion of the second metal layer 122 may be embedded in the first insulating layer 110, and another portion of the second metal layer 122 may protrude onto the first insulating layer 110. As a width of the protruding portion of the first wiring layer 120 may be wider than a width of the embedded portion of the first wiring layer 120, a width of the second metal layer 122 forming the protruding portion may be wider than a width of the second metal layer 122 forming the embedded portion. This is related to the width of the protruding portion and the width of the embedded portion of the first wiring layer 120, and since the first metal layer 121 may have a certain thickness as a seed for the second metal layer 122, the width of the second metal layer 122 may have the above-described differences.

At least a portion of a side surface of the protruding portion of the first wiring layer 120 may have an inclined surface. This may mean that a side surface of the first metal layer 121 forming the protruding portion of the first wiring layer 120, or at least a portion of a side surface of the second metal layer 122 forming the protruding portion of the first wiring layer 120 may have an inclined surface, but the present disclosure is not limited thereto, and may mean that at least a portion of the side surface of the first metal layer 121 and the side surface of the second metal layer 122 may have an inclined surface.

In addition, the present disclosure is not limited thereto, and the inclined surface formed on the side surface of the first metal layer 121 may extend from the inclined surface formed on at least a portion of the side surface of the second metal layer 122, so that the inclined surface of the first metal layer 121 and the inclined surface of the second metal layer 122 may be integrated. The fact that the inclined surface of the first metal layer 121 and the inclined surface of the second metal layer 122 may be integrated may mean that an inclination angle formed by the inclined surface of the first metal layer 121 and the first insulating layer 110 is substantially the same as an inclined angle formed by a virtual extension surface of the inclined surface of the second metal layer 122 and the first insulating layer 110.

The side surface of the first metal layer 121 forming the protruding portion of the first wiring layer 120 may have an inclined surface. Since the first metal layer 121 functions as a seed for the second metal layer 122, a portion of the first metal layer 121 may be removed in an operation of removing a portion of the seed during the manufacturing operations, and in this case, an inclined surface may be formed on the side surface of the first metal layer 121. In other words, the inclined surface formed on the side surface of the first metal layer 121 may be formed in the operation of removing a portion of the seed, and may be formed when the operation of removing the seed is performed by an etching method, but the present disclosure is limited thereto. Meanwhile, the side surface of the first metal layer 121 may have a tapered shape so that the width thereof becomes narrower toward the first insulating layer 110. That is, the side surface of the first metal layer 121 may have a shape tapered downwardly. This may occur when the operation of removing a portion of the seed is performed isotropically, and may occur because more of a lower portion of the first metal layer 121 is removed than an upper portion of the first metal layer 121. In this case, the width of the first metal layer 121 may mean a distance between one side surface of the first metal layer 121 and the other side surface, opposite to the one side surface thereof, with respect to the first metal layer 121 forming the protruding portion of the first wiring layer 120. In other words, the distance may mean a horizontal distance between the side surfaces of the first metal layer 121 forming the protruding portion of the first wiring layer 120.

As the first metal layer 121 and the second metal layer 122 may include substantially the same metal material, in the operation of removing a portion of the seed during the manufacturing operation, not only a portion of the first metal layer 121 but also a portion of the second metal layer 122 may be removed together. As a portion of the second metal layer 122 may be removed, an inclined surface may also be formed on the side surface of the second metal layer 122. In addition, as a portion of the first metal layer 121 and a portion of the second metal layer 122 can be removed at the same time, the inclined surface formed on the side surface of the first metal layer 121 may extend from the inclined surface formed on the side surface of the second metal layer 122. That is, the inclined surface of the first metal layer 121 and the inclined surface of the second metal layer 122 can be integrally formed. Meanwhile, since a portion of the second metal layer 122 may be removed in the operation of removing a portion of the seed, an inclined surface may be formed only in a portion of the second metal layer 122 adjacent to the first metal layer 121. However, the present disclosure is not limited thereto, and an inclined surface may be formed from the upper surface of the second metal layer 122, or an inclined surface may not be formed in the second metal layer 122 and an inclined surface may be formed only in the first metal layer 121. As the side surface of the first metal layer 121 and/or the side surface of the second metal layer 122 may have an inclined surface, the protruding portion of the first wiring layer 120 may be formed to have a width of a lower end portion, narrower than a width of an upper end portion.

Meanwhile, a shape of the inclined surface formed on the side surface of the first metal layer 121 and the inclined surface formed in at least a portion of the side surface of the second metal layer 122 is not limited to those shown in FIG. 3, and in addition, the shape of the inclined surface may be included without limitation as long as it is the shape of the first wiring layer 120 which may occur in an operation of removing a plating seed. For example, the shape thereof may have a structure in which all of the first metal layer 121 forming the protruding portion of the first wiring layer 120 is removed, and have an hourglass-like shape in which the width of the protruding portion of the first wiring layer 120 is narrower than the width of the embedded portion of the first wiring layer 120.

Since the printed circuit board according to an example includes an embedded portion in which a portion of the first wiring layer 120 is embedded in the first insulating layer 110, even though each of the side surfaces of the first metal layer 121 and/or the second metal layer 122 has an inclined surface, the first wiring layer 120 may not be peeled off from the first insulating layer 110. When the printed circuit board includes fine wiring, undercut may occur in the operation of removing a seed, causing a defect in which the wiring is peeled off from the insulating layer and falls off. However, in the printed circuit board according to an example, since a contact area between the first insulating layer 110 and the first wiring layer 120 may be further increased, as the first wiring layer 120 is embedded in a portion of the first insulating layer 110, even if undercut occurs in the operation of removing a seed, adhesion can be secured. That is, as the first wiring layer 120 is formed to fill the groove portion formed in the first insulating layer 110, the contact area between the first wiring layer 120 and the first insulating layer 110 increases by an area corresponding to the side wall of the groove portion. In addition, since a region in which the undercut of the first wiring layer 120 occurs when the seed is removed is not only in close contact with the first insulating layer 110, but also is connected to an embedded region of the first wiring layer 120, the first wiring layer 120 may be prevented from being separated from the first insulating layer 110. Since the region in which the undercut has occurred in the first wiring layer 120 and the embedded portion of the first wiring layer 120 are formed integrally, even if undercut occurs due to a bonding force between the embedded portion and the protruding portion of the first wiring layer 120 including a metal material having the same component, no defects may occur. That is, when a portion of the first wiring layer 120 is not embedded, the bond should be maintained only by an adhesive force between the first wiring layer 120 and the first insulating layer 110, so it may be more advantageous for a portion of the first wiring layer 120 to be embedded in the first insulating layer 110.

The printed circuit board according to an example may further include a second wiring layer 130 disposed below the first insulating layer 110. The fact that the second wiring layer 130 is disposed below the first insulating layer 110 may mean that the second wiring layer 130 is embedded in a lower surface of the first insulating layer 110, as shown in FIG. 3. However, the present disclosure is not limited thereto, and the second wiring layer 130 may be disposed on the lower surface of the first insulating layer 110 and have a protruding structure. The fact that the second wiring layer 130 is embedded in the lower surface of the first insulating layer 110 may mean that the remaining surface excluding the lower surface of the second wiring layer 130 is covered by the first insulating layer 110, and the lower surface of the second wiring layer 130 is not covered by the first insulating layer 110 and may include a structure exposed by the lower surface of the first insulating layer 110.

Meanwhile, the second wiring layer 130 may be spaced apart from the first wiring layer 120. The fact that the second wiring layer 130 is spaced apart from the first wiring layer may mean that the embedded region of the first wiring layer 120 does not directly contact the second wiring layer 130. In other words, this may mean that the embedded portion of the first wiring layer 120 has a different component from a via that performs interlayer connection and can be distinguished from the via. This is because the embedded portion of the first wiring layer 120 does not penetrate substantially all of the first insulating layer 110, but penetrate only a portion of the first insulating layer 110.

The second wiring layer 130 may include a metal material. The metal material may be copper (Cu), aluminum (Al), silver (Ag), tin (Sn), gold (Au), lead (Pb), titanium (Ti), or alloys thereof. The second wiring layer 130 may preferably include copper (Cu), but the present disclosure is not limited thereto. The second wiring layer 130 may be formed using any one of a semi-additive process (SAP), a modified semi-additive process (MSAP), a tenting (TT) method, or a subtractive method, but is not limited thereto. The second wiring layer 130 may include an electroless plating layer (or chemical copper) as a seed layer and an electrolytic plating layer (or electrolytic copper) as a plating layer, but is not limited thereto. A sputtering layer may be formed instead of chemical copper as an electroless plating layer. If necessary, copper foil may be further included. The second wiring layer 130 may perform various functions depending on the design. For example, the second wiring layer 130 may include a signal pattern, a power pattern, a ground pattern, and the like, but is not limited thereto, and may function as a pad for mounting electronic components, chips, and the like, or as a pad for connection to another board. Each of these patterns can have various forms such as lines, planes, pads, and the like.

The first wiring layer 120 may have a greater wiring density than the second wiring layer 130. That is, the first wiring layer 120 may include a finer wiring than a wiring of the second wiring layer 130. The fact that the wiring density is higher is a relative concept, and may mean, for example, that an average pitch of the wiring included in the first wiring layer 120 may be smaller than an average pitch of the wiring included in the second wiring layer 130. The pitch of may be measured by photographing a cut cross section of the printed circuit board using a scanning microscope, and the average pitch may be an average value of the pitch between wirings measured at five arbitrary points. That is, the wiring included in the first wiring layer 120 may be a high-density fine wiring with a smaller line/space (L/S) than the wiring included in the second wiring layer 130. As a non-limiting example, the line/space of the wiring included in the first wiring layer 120 may be approximately 2/2 μm, but the present disclosure is not limited thereto. As a portion of the first wiring layer 120 is embedded in the first insulating layer 110, a finer wiring than that of the second wiring layer 130 may be implemented in the first wiring layer 120, and the wiring of the first wiring layer 120 The density may be greater than the wiring density of the second wiring layer 130. Meanwhile, in FIG. 3, the thickness of the first wiring layer 120 and the thickness of the second wiring layer 130 are shown to be almost similar, but the present disclosure is not limited, and as the first wiring layer 120 may be formed to be finer than the second wiring layer 130, the thickness of the first wiring layer 120 may be thinner than the thickness of the second wiring layer 130.

The printed circuit board according to an example is not limited to the components shown in FIG. 3, and FIG. 3 illustrates only a portion of the printed circuit board, and other components may be further included. For example, other components such as an insulating layer, a circuit, an interlayer via, and the like may be further included below the first insulating layer 110. An insulating layer, a circuit, and an interlayer via may also be further included above the first insulating layer 110. In other words, additional components that can be used by anyone skilled in the art in the relevant technical field may be further included.

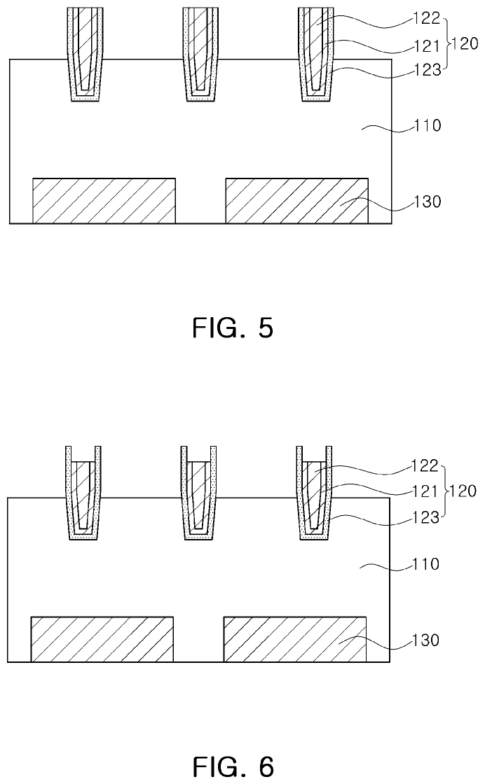

FIG. 4 is a cross-sectional view schematically illustrating a printed circuit board according to another example.

Referring to FIG. 4, the first wiring layer 120 of the printed circuit board according to another example may further include a third metal layer 123 disposed below the first metal layer 121. Like the first metal layer 121, a portion of the third metal layer 123 may be embedded in the first insulating layer 110, and another portion of the third metal layer 123 may be disposed on the first insulating layer 110. The third metal layer 123 may be conformally disposed along the groove portion formed in the first insulating layer 110. That is, the third metal layer 123 may be formed along an inner wall of the groove portion formed in the first insulating layer 110, and may be disposed to extend to an upper surface of the first insulating layer 110.

The third metal layer 123 may include one metal material from the group of metal materials of the above-described first wiring layer 120. The third metal layer 123 may include a different metal material from the first metal layer 121. In addition, the third metal layer 123 may include a different metal material from the second metal layer 122. The third metal layer 123 may preferably include titanium (Ti), but the present disclosure is not limited thereto, and the third metal layer 123 may be comprised of a plurality of metal layers in some cases. In this case, when the third metal layer 123 is composed of a plurality of metal layers, each of the plurality of metal layers may include different metal materials. The third metal layer 123 may be formed before the first metal layer 121 is formed. The third metal layer 123 may be disposed between the first metal layer 121 and the first insulating layer 110 to ensure adhesion of the first metal layer 121. The third metal layer 123 may include a sputtering layer, but the present disclosure is not limited thereto. As the third metal layer 123 may include a sputtering layer, the first metal layer 121 may also include a sputtering layer, but the present disclosure is not limited thereto.

A side surface of the third metal layer 123 may have an inclined surface. The side surface of the third metal layer 123 forming the protruding portion of the first wiring layer 120 may have an inclined surface. The side surface of the third metal layer 123 may have the same meaning as the side surface of the first metal layer 121. That is, the side surface of the third metal layer 123 may refer to a side surface of a region disposed on the upper surface of the first insulating layer 110. Since the third metal layer 123 may be conformally disposed on the first insulating layer 110 before the first metal layer 121 is formed, an operation of removing a portion of the third metal layer 123 may be included in the operation of completing the first wiring layer 120. When the operation of removing a portion of the third metal layer 123 is performed by an etching method, the side surface of the third metal layer 123 may have an inclined surface in the operation of removing a portion of the third metal layer 123. In this case, since the operation of removing a portion of the third metal layer 123 may be performed after the operation of removing a portion of the first metal layer 121, the inclined surface of the third metal layer 123 may be formed along the inclined surface formed in the first metal layer 121. This may be the result of an etchant penetrating along the inclined surface of the first metal layer 121 when isotropic etching is performed.

In FIG. 4, the inclined surface of the first metal layer 121 and the inclined surface of the third metal layer 123 are shown to be integrated, but the present disclosure is not necessarily limited, and the inclined surface of the first metal layer 121 and the inclined surface of the third metal layer 123 may have various shapes. Since the third metal layer 123 may include a different metal material from the first metal layer 121 and the second metal layer 122, in the operation of removing a portion of the first metal layer 121, the third metal layer 123 may not react, and in the operation of removing a portion of the third metal layer 123, the first metal layer 121 and the second metal layer 122 may not react, so that the third metal layer 123 may have various shapes. For example, the inclined surface of the first metal layer 121 and the inclined surface of the third metal layer 123 may have different inclination angles, but the present disclosure is not limited thereto, and may also have a shape in which the side surface of the third metal layer 123 protrudes more than the first metal layer 121, at the contact surface between the third metal layer 123 and the first metal layer 121.

Meanwhile, since the same configuration as that of the printed circuit board according to an example among the configurations other than the information regarding the third metal layer 123 may be applied to a printed circuit board according to another example, and thus, duplicate descriptions thereof will be omitted.

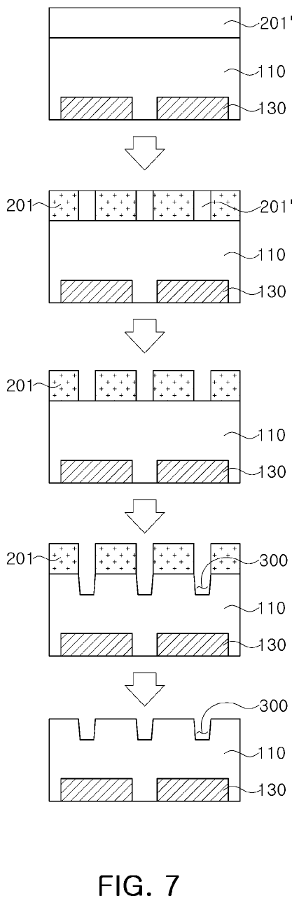

FIG. 5 is a cross-sectional view schematically illustrating a printed circuit board according to another example.

Referring to FIG. 5, in the printed circuit board according to another example, the first wiring layer 120 may protrude onto the first insulating layer 110 without extending on the upper surface of the first insulating layer 110. That is, a portion of the first wiring layer 120 may form an embedded portion embedded in the first insulating layer 110, and another portion of the first wiring layer 120 may form a protruding portion protruding onto the first insulating layer 110. In this case, an upper surface of the first wiring layer 120 may be located higher than the upper surface of the first insulating layer 110.

In the printed circuit board according to another example, since a third metal layer 123 is formed without removing the dry film formed on the first insulating layer 110, the third metal layer 123 may be formed along a wall surface of an opening formed in the dry film. Since the dry film is removed in a subsequent operation, the third metal layer 123 may be disposed on the first insulating layer 110 along a shape of the opening formed in the dry film. That is, since the third metal layer 123 and the first metal layer 121 are formed directly without removing the dry film for forming the groove portion, the first wiring layer 120 may not extend on the upper surface of the first insulating layer 110. Accordingly, the protruding portion of the first wiring layer 120 may have a substantially constant width.

Among the configurations other than the disposition and shape of the first wiring layer 120, the same configuration as the printed circuit board according to an example and the printed circuit board according to another example may be applied to the printed circuit board according to another example, and thus, duplicate descriptions thereof will be omitted.

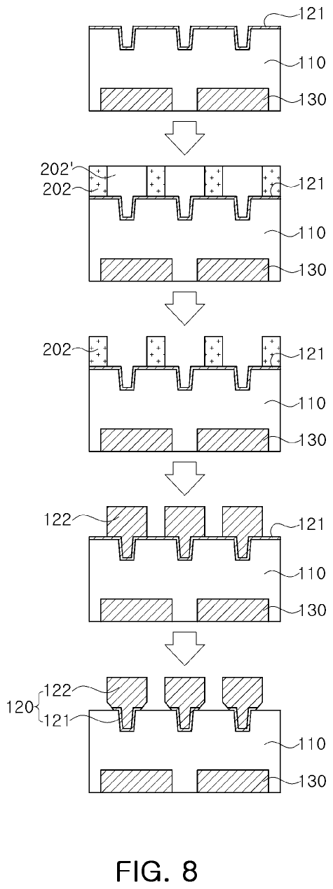

FIG. 6 is a cross-sectional view schematically illustrating a printed circuit board according to another example.

Referring to FIG. 6, in the printed circuit board according to another example, the first wiring layer 120 may have a region in which at least a portion of the first metal layer 121 and the second metal layer 122 are recessed.

Meanwhile, the first wiring layer 120 may have a step formed between the third metal layer 123 and the first metal layer 121 and/or the second metal layer 122.

This may occur when each of the first metal layer 121 and the second metal layer 122 includes substantially the same metal material as a seed layer, and specifically, this may occur when each of the first metal layer 121, the second metal layer 122, and the seed layer 140 includes copper (Cu). In an operation of removing the seed layer, portions of the first metal layer 121 and the second metal layer 122, including substantially the same metal material as the seed layer, may be removed, respectively. The operation of removing the seed layer will be described later in the method of manufacturing a printed circuit board. Meanwhile, in FIG. 6, the recessed region is shown as having a flat surface, but the present disclosure is not limited thereto, and a surface of the recessed region may be uneven. Alternatively, the recessed region may have a concave shape at a center, such as a dimple phenomenon, or, conversely, may have a convex shape at the center, and the recessed shape may be unlimited. Among the configurations other than the disposition and shape of the first wiring layer 120, since the same configuration as the printed circuit board according to an example, the printed circuit board according to another example, and the printed circuit board according to another example may be applied to the printed circuit board according to another example, and thus, duplicate descriptions thereof will be omitted.

### Manufacturing Method of Printed Circuit Board

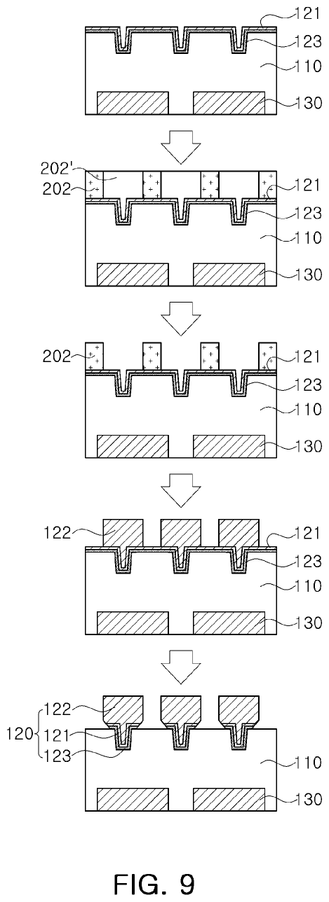

FIGS. 7 and 8 are cross-sectional views schematically illustrating a manufacturing method of a printed circuit board according to an example.

The manufacturing method of a printed circuit board according to an example may include forming a groove portion 300 penetrating a portion of the first insulating layer 110, and forming a first wiring layer 120 including an embedded portion filling the groove portion 300 and a protruding portion protruding onto the first insulating layer 110. In this case, forming the first wiring layer 120 may include forming a first metal layer 121 along the groove portion 300 and an upper surface of the first insulating layer 110 and a second metal layer 122 on the first metal layer 121, and may include removing a portion of the first metal layer 121. In the operation of removing a portion of the first metal layer 121, a width of a lower end portion of the protruding portion of the first wiring layer 120 may be narrower than a width of an upper end portion thereof.

Referring to FIG. 7, a manufacturing method of a printed circuit board according to an example may include forming a dry film 201 on the first insulating layer 110. Forming the dry film 201 may include stacking a dry film 201′ and patterning the dry film 201 through exposure and development processes. An opening may be formed in the dry film 201, and a groove portion may be formed in the first insulating layer 110 to correspond to the opening. The dry film 201 may be any known dry film, and any material having a different reactivity from that of the first insulating layer 110 in the operation of removing a portion of the first insulating layer 110 may be used without limitation. Meanwhile, in FIG. 7, the operations of forming a dry film 201 containing a photosensitive insulating material and exposing and developing the same are shown, but an embodiment thereof is not limited thereto. In the operation of forming the groove portion 300 in a portion of the first insulating layer 110, any material that can function as a mask or resist can be used without limitations, and material and processing methods that may be used by anyone skilled in the art may be used.

In this case, a second wiring layer 130 may be embedded below the first insulating layer 110. More specifically, the method of manufacturing a printed circuit board according to an example may be performed after forming the first insulating layer 110 on the second wiring layer 130. As described above in the printed circuit board according to an example, other components of the printed circuit board may be further included below the first insulating layer 110.

After forming the dry film 201 on the first insulating layer 110, forming a groove portion penetrating a portion of the first insulating layer 110 may be included. As described above in the printed circuit board according to an example, a groove portion 300 may be a location in which an embedded portion of the first wiring layer 120 is formed. The groove portion 300 may not completely penetrate the first insulating layer 110. Since the groove portion 300 does not completely penetrate the first insulating layer 110, the second wiring layer 130 may not be exposed by the groove portion, and then even if the first wiring layer 120 is formed to fill the groove portion 300, the first wiring layer 120 and the second wiring layer 130 may be maintained to be spaced apart from each other. That is, the groove portion 300 penetrating a portion of the first insulating layer 110 may have a different component from a via hole performing interlayer connection. The groove portion 300 can be formed by etching the first insulating layer 110, and the width and depth of the groove portion may be set through an opening formed in the dry film 201. In other words, the dry film 201 may correspond to a mask or resist for forming the groove portion 300.

After forming the groove portion 300, the dry film 201 can be removed. The dry film 201 may be removed using any method that can be used by those skilled in the art.

Referring to FIG. 8, a first metal layer 121 may be formed on the first insulating layer 110. The first metal layer 121 may function as a seed for forming a second metal layer 122, which will be described later, and the first metal layer 121 may be formed by performing electroless plating, and in some cases, the first metal layer 121 may also be formed by sputtering, or the like. The first metal layer 121 may be formed along a boundary of the groove portion 300, and may be formed to extend to the upper surface of the first insulating layer 110. The method of forming the first metal layer 121 may be a method with excellent step coverage. Since the thickness of the first metal layer 121 may be thin, the first metal layer 121 may not be formed to fill the groove portion 300, but may be formed conformally according to an external shape of the groove portion 300.

Thereafter, a dry film 202′ may be disposed and exposed and developed to form a dry film 202. The dry film 202 may include an opening, and may be a region for forming the second metal layer 122. The opening of the dry film 202 may be formed to correspond to the opening. The dry film 202 may include the same material as the previous dry film 201, but the present disclosure is not limited thereto, it may be used without limitation as long as the dry film 202 may function as a plating resist or mask for forming the second metal layer 222 to be described later. The dry film 202 may be formed using any method that can be used by those skilled in the art.

Thereafter, the second metal layer 122 may be formed. The second metal layer 122 may be formed through electroplating using the first metal layer 121 as a seed, but the present disclosure is not limited thereto.

Thereafter, the dry film 202 may be removed. The dry film 202 may be removed using any method that can be used by those skilled in the art. In the operation of removing the dry film 202, the first metal layer 121 and the second metal layer 122 may not be deformed.

Thereafter, a portion of the first metal layer 121 may be removed to complete the first wiring layer 120. Since the first metal layer 121 functions as a seed, the first metal layer 121 enables adjacent first wiring layers 120 to perform necessary functions without short-circuiting through an operation of removing the unnecessary first metal layer 121 after the second metal layer 122 is formed. The operation of removing a portion of the first metal layer 121 may be performed using an etching method. More specifically, the operation may be performed using flash etching, but the present disclosure is not limited thereto. The operation of removing a portion of the first metal layer 121 is performed to remove unnecessary portions of the seed, and any method that can be used by those skilled in the art may be used.

In this case, an undercut may occur in at least a portion of the first wiring layer 120. The occurrence of an undercut in at least a portion of the first wiring layer 120 may mean that a portion of the first metal layer 121 disposed below the second metal layer 122 may be removed, and a portion of the second metal layer 122 may also be removed together. Since, in the printed circuit board according to an example, the first wiring layer 120 having an embedded portion embedded in the first insulating layer 110 is formed, even if undercut occurs in the operation of removing a portion of the first metal layer 121, a defect in which the first wiring layer 120 is peeled off from the first insulating layer 110 may not occur.

Meanwhile, as described above, the method of manufacturing a printed circuit board according to an example is not limited to the contents shown in FIGS. 7 and 8. As described above in the components of the printed circuit board according to an example, other components may be further included on the lower surface of the first insulating layer 110. An operation of forming other components on the first insulating layer 110 after the first wiring layer 120 is completed may be further included.

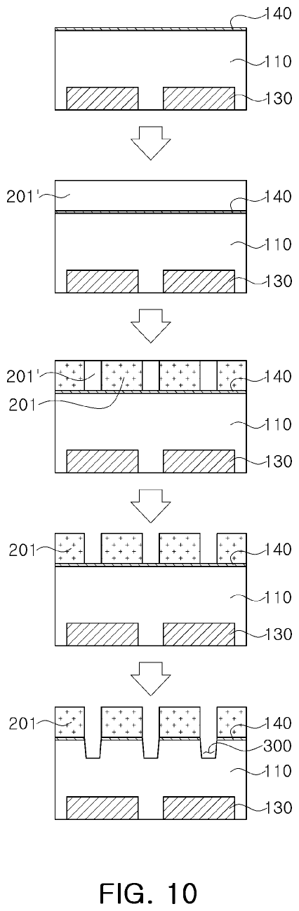

FIG. 9 is a cross-sectional view schematically illustrating a portion of a method of manufacturing a printed circuit board according to another example.

A method of manufacturing a printed circuit board according to another example may include forming a groove portion 300 above the first insulating layer 110 as in the method of manufacturing a printed circuit board according to an example. A method of manufacturing a printed circuit board according to another example will be described focusing on the operation of forming a groove portion 300.

Referring to FIG. 9, an operation of forming a third metal layer 123 and an operation of forming a first metal layer 121 may be included. The operation of forming the first metal layer 121 may be included before the operation of forming the first metal layer 121. The operation of forming the third metal layer 123 may be performed by sputtering, but the present disclosure is not limited thereto. In this case, the operation of forming the first metal layer 121 may also be performed by sputtering. When the operation of forming the third metal layer 123 and the operation of forming the first metal layer 121 are performed by the same method, the operation of forming the first metal layer 121 may be performed immediately after the operation of forming the third metal layer 123. The third metal layer 123 may be a means to secure adhesion to the first metal layer 121, and the third metal layer 123 may include a different metal material from the first metal layer 121.

Thereafter, the dry film 202 may be formed as a plating resist, the second metal layer 122 may be formed, and the dry film 202 may be removed.

Thereafter, an operation of removing a portion of the first metal layer 121 and an operation of removing the third metal layer 123 may be included. The operation of removing a portion of the first metal layer 121 may be the same as the method of manufacturing a printed circuit board according to an example, and the operation of removing a portion of the third metal layer 123 may be performed by the same method as in the operation of removing the first metal layer 121.

In this case, since the first metal layer 121 and the third metal layer 123 may include different metal materials, the third metal layer 123 may not react in the operation of removing a portion of the first metal layer 121, and the first metal layer 121 may not react in the operation of removing the third metal layer 123. Meanwhile, as described above in the printed circuit board, the specific shapes of the first metal layer 121 and the third metal layer 123 are not limited to FIG. 8 and may vary.

Meanwhile, among operations other than the operation of forming the third metal layer 123 and the operation of removing a portion of the third metal layer 123, the same operations as the method of manufacturing the printed circuit board according to the example may also be applied to the printed circuit board according to another example, and thus, duplicate descriptions thereof will be omitted.

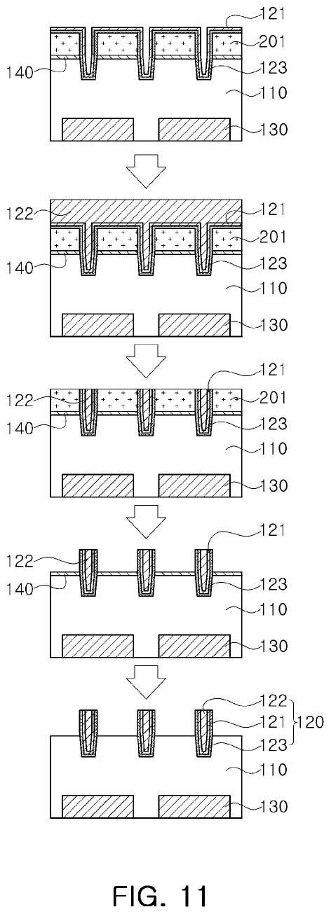

FIGS. 10 and 11 are cross-sectional views schematically illustrating a method of manufacturing a printed circuit board according to another example.

Referring to FIG. 10, a method of manufacturing a printed circuit board according to another example may include an operation of forming a seed layer 140 on the first insulating layer 110. The seed layer 140 may be formed by performing electroless plating, and in some cases, may be formed by sputtering, or the like. As a non-limiting example, the first insulating layer 110 to which the seed layer 140 is attached in a form of copper foil may be used. The seed layer 140 is a temporary component and may not remain in a finished product. The seed layer 140 may function as a seed complementing the third metal layer 123 and the first metal layer 121 in the operation of forming a second metal layer 122, to be described later. Therefore, in some cases, the operation of forming the seed layer 140 may be omitted. The seed layer 140 may include a metal material, and may be selected from the same group of materials as the metal material of the first wiring layer 120, and may preferably include copper (Cu), but the present disclosure is limited thereto.

Thereafter, a dry film 201 may be formed on the seed layer 140. The operation of forming the dry film 201 may include an operation of forming a dry film 201′ and exposing and developing the same.

Thereafter, an operation of forming a groove portion 300 penetrating a portion of the seed layer 140 and the first insulating layer 110 may be included. The operation of forming the groove portion 300 may be performed by an operation of penetrating the seed layer 140 and penetrating a portion of the first insulating layer 110, respectively, but the present disclosure is not limited thereto, and the portions of the seed layer 140 and the first insulating layer 110 may be penetrated at the same time. When the groove portion 300 penetrating a portion of the first insulating layer 110 is formed in a separate process after the operation of penetrating the seed layer 140, the groove portion 300 may be formed in the same manner as in the method of manufacturing the printed circuit board according to an example, and when the seed layer 140 and the first insulating layer 110 are processed simultaneously, mechanical processing can be performed. As the seed layer 140 is disposed on the first insulating layer 110, when the groove portion 300 is formed in the first insulating layer 110, it may be more advantageous to adjust a degree of processing so as not to completely penetrate the first insulating layer 110.

Referring to FIG. 11, an operation of forming a third metal layer 123 and an operation of forming a first metal layer 121 may be included. In the printed circuit board according to another example, the third metal layer 123 and the first metal layer 121 are formed without removing the dry film 201, so the third metal layer 123 may not contact the upper surface of the first insulating layer 110, and the third metal layer 123 and the first metal layer 121 may be disposed to extend onto the dry film 201.

Thereafter, an operation of forming a second metal layer 122 may be included. The operation of forming the second metal layer 122 may be performed by electroplating using the first metal layer 121 as a seed. Meanwhile, the second metal layer 122 may be plated beyond the first metal layer 121 disposed on the dry film 201 after filling all of the groove portions 300. That is, the operation of forming the second metal layer 122 may be performed by panel plating or over-plating, but the present disclosure is not limited thereto. Since the third metal layer 123 and the first metal layer 121 are disposed on the dry film 201, it may be difficult to cover both the opening of the dry film 201 and the groove portion 300 of the first insulating layer 110. That is, it may not be easy to form the third metal layer 123 and the first metal layer 121 on the inner wall of the groove portion 300, the inner wall of the opening of the dry film 201, and the upper surface of the dry film 201. Accordingly, since the third metal layer 123 and the first metal layer 121 may not be sufficient as seeds for forming the second metal layer 122, the seed layer 140 formed on the first insulating layer 110 may complement this. That is, in the operation in which the seed layer 140 is disposed on the first insulating layer 110 in advance and the second metal layer 122 is formed, the seed layer 140 may function as an auxiliary to the third metal layer 123 and the first metal layer 121.

Thereafter, an operation of removing a portion of the second metal layer 122 may be included. The operation of removing a portion of the second metal layer 122 may be performed by removing the over-plated portion of the second metal layer 122, and may be performed using at least one of a chemical-mechanical polishing (CMP) process and an etching process, but the present disclosure is not limited thereto. In this case, when the operation is performed through a chemical-mechanical polishing process, portions of the first metal layer 121 and the third metal layer 123 may also be removed and have a flat surface. On the other hand, when the operation is performed as an etching process, the third metal layer 123 including a different metal material from the second metal layer 122 may not react, the second metal layer 122 may be over-etched, and a portion of the first metal layer 121 including substantially the same metal material as the second metal layer 122 may be removed together to form a recessed region of the first wiring layer 120.

Thereafter, an operation of removing the seed layer 140 may be included. Since the seed layer 140 may include the same metal material as the first metal layer 121 and the second metal layer 122, the seed layer 140 may include a different metal material from the third metal layer 123. Therefore, even in the operation of removing the seed layer 140, the third metal layer 123 may not react. That is, the third metal layer 123 may function as an etching barrier separating the first metal layer 121 and the second metal layer 122 from the seed layer. By removing the seed layer 140, the first wiring layer 120 can be completed.

Among the configurations and operations other than the formation of the first wiring layer 120 and the seed layer 140, the same configurations and operations as the operation for manufacturing a printed circuit board according to an example and the method for manufacturing a printed circuit board according to another example may also be applied to the method for manufacturing a printed circuit board according to another example, and thus, duplicate descriptions thereof are omitted.

Meanwhile, as described above, in the method of manufacturing a printed circuit board according to another example, portions of the first metal layer 121 and the second metal layer 122 may be further removed in the operation of removing the seed layer 140, and as described above, in the operation of removing a portion of the second metal layer 122, the first wiring layer 120 may have a region in which the first metal layer 121 and the second metal layer 122 are recessed.

As set forth above, as one of the many effects of the present disclosure, a printed circuit board in which a wiring layer having a fine pitch may be implemented, and a manufacturing method of the printed circuit board may be provided.

As another effect of the various effects of the present disclosure, a printed circuit board in which a wiring layer of which a portion thereof is embedded and another portion thereof protrudes may be implemented, and a manufacturing method of the printed circuit board may be provided.

As another effect of the various effects of the present disclosure, a printed circuit board that can improve reliability and a manufacturing method of the printed circuit board may be provided.

In the present disclosure, the meaning of cross-section may mean the cross-sectional shape when the object is cut vertically, or the cross-sectional shape when the object is viewed from a side view. Additionally, the meaning on a plane may be the shape when the object is cut horizontally, or the plane shape when the object is viewed from a top-view or bottom-view.

In the present disclosure, upper surface, upper surface, upper surface, etc. are used for convenience to refer to the direction toward the surface on which electronic components may be mounted based on the cross section of the drawing, and lower side, bottom, lower surface, etc. are used in the opposite direction. However, this direction is defined for convenience of explanation, and of course, the scope of the patent claims is not particularly limited by the description of this direction.

In the present disclosure, the meaning of connected is a concept that includes not only directly connected, but also indirectly connected through an adhesive layer or the like. In addition, the meaning of being electrically connected is a concept that includes both cases where it is physically connected and cases where it is not connected. Additionally, expressions such as first, second, etc. are used to distinguish one component from another component and do not limit the order and/or importance of the components. In some cases, the first component may be named the second component without departing from the scope of rights, and similarly, the second component may be named as the first component.

In the present disclosure, it may be substantially determined by including process errors, position deviations, errors during measurement, and the like, which occur during the manufacturing process. For example, being substantially constant may include a case of having exactly the same numerical values, but also a case of being approximately the same. As another example, substantially vertical may include not only completely vertical, but also approximately vertical. As another example, substantially coplanar may include not only a case of being completely on the same plane, but also a case of being approximately on the same plane.

In the present disclosure, a width of a certain component may be measured by photographing a cut cross-section in a stacking direction with a scanning microscope or the like. The width of the component can be interpreted as the distance across a certain component horizontally, but may include measurement errors or errors in the manufacturing process. For example, the width of the configuration may be a value by averaging horizontal distances measured at five arbitrary points.

In the present disclosure, a thickness of a certain component can be measured by photographing a cross section cut in the stacking direction with a scanning microscope or the like. The thickness of a component can be interpreted as a distance across the component vertically, but may include measurement errors or errors in the manufacturing process. For example, the thickness of the component may be a value by averaging vertical distances measured at five arbitrary points.

In the present disclosure, the same material or substance may mean not only the exact same material but also the same type of material. Accordingly, the composition of the materials is substantially the same, but specific composition ratios thereof may be slightly different.

The expression ‘example’ used in the present disclosure does not mean identical embodiments, but is provided to emphasize and explain different unique features. However, the examples presented above do not exclude being implemented in combination with features of other examples. For example, even if what is described in an example is not described in another example, unless there is a contrary or contradictory explanation in another example, it may be understood as an explanation related to another example.

The terminology used in this disclosure is used to describe examples only and is not intended to limit the disclosure. At this time, singular expressions include plural expressions, unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board, comprising:
a first insulating layer including a groove portion on an upper side; and
a first wiring layer having an embedded portion embedded in the groove portion and a protruding portion protruding onto the first insulating layer,
wherein the protruding portion of the first wiring layer has a width of a lower end portion, narrower than a width of an upper end portion.

2. The printed circuit board of claim 1, wherein the first wiring layer comprises a first metal layer disposed on an inner wall of the groove portion and extending along a portion of an upper surface of the first insulating layer, and a second metal layer disposed on the first metal layer,
wherein a width of a portion of the first metal layer, adjacent to the upper surface of the first insulating layer is narrower than a width of an upper surface of the first metal layer.

3. The printed circuit board of claim 2, wherein a width of a portion of the second metal layer, adjacent to the upper surface of the first insulating layer is narrower than a width of an upper surface of the second metal layer.

4. The printed circuit board of claim 2, wherein at least a portion of a side surface of the second metal layer in the protruding portion has an inclined surface.

5. The printed circuit board of claim 4, wherein a side surface of the first metal layer in the protruding portion has an inclined surface, and
an inclination angle between the inclined surface of the first metal layer and the upper surface of the first insulating layer is substantially the same as an inclination angle between an extension surface of the inclined surface included in at least the portion of the side surface of the second metal layer and the upper surface of the first insulating layer.

6. The printed circuit board of claim 2, wherein the first metal layer comprises substantially the same metal as the second metal layer.

7. The printed circuit board of claim 2, wherein the first wiring layer comprises a third metal layer disposed below the first metal layer, and
the third metal layer comprises a different metal from the first metal layer.

8. The printed circuit board of claim 1, wherein a width of the embedded portion is narrower than a width of the protruding portion.

9. The printed circuit board of claim 1, further comprising:
a second wiring layer disposed below the first wiring layer, and spaced apart from the first wiring layer.

10. A printed circuit board, comprising:
a first insulating layer including a groove portion on an upper side;
a first wiring layer having an embedded portion embedded in the groove portion and a protruding portion protruding onto the first insulating layer; and
a second wiring layer embedded in the first insulating layer, and disposed below and spaced apart from the first wiring layer,
wherein a wiring density of the first wiring layer is greater than a wiring density of the second wiring layer.

11. The printed circuit board of claim 10, wherein the protruding portion of the first wiring layer has a substantially constant width.

12. The printed circuit board of claim 11, wherein a width of an upper portion of the embedded portion is substantially the same as a width of a lower portion of the protruding portion.

13. The printed circuit board of claim 10, wherein the first wiring layer comprises a first metal layer disposed on an inner wall of the groove portion and extending to protrude onto the first insulating layer, a second metal layer disposed on the first metal layer, and a third layer disposed on the second metal layer.

14. The printed circuit board of claim 13, wherein the second metal layer comprises a different metal than the first metal layer.

15. The printed circuit board of claim 14, wherein the second metal layer and the third metal layer comprise substantially the same metal as each other.

16. The printed circuit board of claim 13, wherein the first wiring layer has a region in which at least a portion of the second metal layer and the third metal layer are recessed.

17. A printed circuit board, comprising:
an insulating layer including a groove portion on an upper side; and
a wiring layer having an embedded portion embedded in the groove portion and a protruding portion protruding onto the insulating layer,
wherein the wiring layer comprises a first metal layer disposed on an inner wall of the groove portion, a second metal layer disposed on the first metal layer, and a third layer disposed on the second metal layer,
each of the first, second, and third metal layer includes a portion disposed in the groove portion and a portion protruding onto the insulating layer, and
the second metal layer comprises a different metal than the first metal layer.

18. The printed circuit board of claim 17, wherein the second metal layer comprises a different metal than the third metal layer.

19. The printed circuit board of claim 18, wherein the first metal layer comprises a different metal than the third metal layer.

20. The printed circuit board of claim 17, wherein the second metal layer and the third metal layer comprise substantially the same metal as each other.
